(19) United States
(12) Patent Application Publication
(10) Pub. No.: US 2002/0197544 A1
(43) Pub. Date: Dec. 26, 2002

(54) Halftone phase shift mask and its manufacturing method

(76) Inventor: Haruo Iwasaki, Tokyo (JP)

Correspondence Address: McGinn & Gibb, PLLC, Suite 200, 8321 Old Courthouse Road, Vienna, VA, 22182-3817, US

(21) Appl. No.: 10/171,552

(22) Filed: Jun. 17, 2002

(30) Foreign Application Priority Data
Jun. 20, 2001 (JP) 2001-185942

(51) Int. Cl. G03F 9/00; G03C 5/00

(52) U.S. Cl. 430/5; 430/322; 430/323; 430/324; 430/296

(57) ABSTRACT

A halftone phase shift mask comprises a transparent substrate, a light shielding film formed on the transparent film for shielding exposure light, and having a first opening, and a halftone phase shift film formed in the first opening on the transparent substrate for shifting the phase of the exposure light, and having a second opening which defines an exposed region.

### BACKGROUND OF THE INVENTION

1. Field of the Invention:

The present invention relates to an exposure mask for forming a desired pattern on a wafer, and more particularly, to a halftone phase shift mask which is suitable for use in forming minute patterns.

2. Description of the Related Art:

As a result of the advancement in higher integration, halftone phase shift masks have been used for exposure of minute patterns such as contact holes in recent semiconductor integrated circuit devices. A halftone phase shift mask enables the formation of a minute pattern of the size less than the resolution which is dominated by the wavelength of light used for the exposure, and is typically utilized for forming minute patterns having widths of 0.5 μm or less.

Structures of conventional halftone phase shift mask and its manufacturing methods are described, for example, in Japanese Patent Applications Laid-open No. 7-287387, 10-186631, 9-325469, 10-83062, and 9-242211.

FIG. 1 illustrates an exemplary structure of conventional halftone shift mask 10.

Halftone phase shift mask 10 comprises transparent glass substrate 11; halftone phase shift film 12 (hereinafter simply called the “halftone film”) formed on glass substrate 11 and having openings (exposed regions) for forming a minute pattern of, for example, contact holes or the like; and light shielding film 13 laminated on halftone film 12 and having openings which are formed wider than the openings of halftone film 12 by a predetermined width.

Light shielding film 13 is generally made of a Cr film which provides a light shielding region for shielding exposure light during exposure. Halftone film 12, which has a predetermined refractive index, is made of a Cr oxide film, a Cr nitride film, an MoSi film or the like. Also, halftone film 12 functions as a translucent region which transmits approximately 6%-30% of the exposure light, and as a phase shift film for shifting the phase of the exposure light. Halftone film 12 is typically formed in such a thickness that delays the phase of the exposure light by approximately 180 degrees (inverts).

The exposure light which transmits halftone phase shift mask 10 experiences inversion of phase at a boundary between the exposed region and translucent region. Therefore, as the exposure light is projected onto a wafer through a lens, portions of light which are introduced into the opposite regions cancel each other near the boundary by the diffraction, so that the exposure light in the translucent region from the boundary is reduced in intensity to zero. In other words, since the exposure light is prevented from extending out of an exposed region, a high resolution pattern can be formed.

FIGS. 2A-2F illustrate steps of manufacturing halftone phase shift mask 10 illustrated in FIG. 1.

First, halftone film 12 and light shielding film 13 are sequentially laminated on transparent substrate 11 (FIG. 2A), and a resist is coated on light shielding film 13 to form resist mask 14 (FIG. 2B).

Next, resist mask 14 is patterned by exposing the same using a known mask drawing apparatus to form resist pattern 14A having a plurality of openings. Then, this resist mask 14A is used as a mask to partially remove light shielding film 13 and halftone film 12, respectively, by dry etching to form openings 15 (FIG. 2C).

Next, after removing resist pattern 14A, a resist is again coated to form new resist film 16. Subsequently, resist mask 16 is patterned using a known mask drawing apparatus (FIG. 2D) to form resist pattern 16A having openings larger than openings 15.

Then, this resist pattern 16A is used as a mask for wet etching using cerium ammonium sulfate. Specifically, light shielding film 13 alone is selectively etched away, while leaving halftone 12 which is exposed by the openings of resist pattern 16A, to form openings 17 larger than openings 15 (see FIG. 2E). Finally, resist pattern 16A is removed to provide a halftone phase shift mask (FIG. 2F).

In the conventional method of manufacturing a halftone phase shift mask described above, as resist film 16 is coated, a rugged pattern is formed by underlying light shielding film 13 and halftone film 12, resulting in formation of like ruggedness on the surface of resist film 16. Rugged resist film 16 thus formed causes a problem of a lower patterning accuracy for resist pattern 16A and resulting difficulties in accurately forming openings 17 through light shielding film 13 in desired dimensions.

Also, in the step of selectively removing light shielding film 13 while leaving halftone film 12 for forming openings 17, since a desired selection ratio is not achieved between light shielding film 13 and halftone film 12, halftone film 12 could be simultaneously removed together if dry etching is used. For this reason, the aforementioned wet etching must be essentially employed in the step of forming openings 17.

However, since the wet etching is inherently isotropic etching, a problem arises in that the dimensional accuracy is further reduced for openings 17 which are formed through light shielding film 13. A pattern formed using the wet etching presents rounded corners of openings 17, for example, as illustrated in FIG. 3, so that the resulting openings are generally in a circular shape. Thus, the accuracy is reduced as well in a pattern on a wafer which is exposed using such halftone phase shift mask 10.

### SUMMARY OF THE INVENTION

It is therefore an object of the present invention to provide a halftone phase shift mask which has such a structure that offers accurate opening dimensions in patterning a light shielding film, and its manufacturing method.

To achieve the above object, a halftone phase shift mask according to the present invention includes a light shielding film formed on a transparent film and having a first opening, and a halftone phase shift film formed in the first opening and having a second opening which defines an exposed region.

With the foregoing structure, since the halftone film is not laminated on the light shielding film as is the case with the prior art, the present invention eliminates a step of selectively removing the light shielding film, and dry etching, which is anisotropy etching, can be used in the step of forming the opening through the light shielding film. Since the dry etching can form openings at a high dimensional accuracy in an etching process which uses a resist as a mask, the opening can be formed through the light shielding film at an improved dimensional accuracy.

Similarly, since the dry etching can also be used for forming the second opening through the halftone film, the opening can be formed through halftone film likewise at an improved dimensional accuracy.

Consequently, a patterning accuracy is improved for a semiconductor integrated circuit device when it is formed through exposure using the halftone phase shift mask having the light shielding film and halftone film.

In another aspect, a method of manufacturing a halftone phase shift mask according to the present invention involves forming a light shielding film having a first opening on a transparent substrate, depositing a halftone film over the entire surface of the light shielding film including the inside of the first opening, polishing away the halftone film by CMP (Chemical Mechanical Polishing) using the light shielding film as a stopper, and forming a second opening through the halftone film remaining in the first opening for defining an exposed region.

In the present invention, since the CMP-based polishing is stopped on the surface of the light shielding film which is accurately formed in a desired thickness by sputtering or the like during the CMP-based polishing of the halftone film, it is possible to accurately control the thickness of the halftone film which functions as a phase shift film.

The above and other objects, features and advantages of the present invention will become apparent from the following description with reference to the accompanying drawings which illustrate examples of the present invention.

### BRIEF DESCRIPTION OF THE DRAWINGS

FIG. 1 is a perspective view illustrating the structure of a conventional halftone phase shift mask;

FIGS. 2A-2F are cross-sectional views illustrating steps of manufacturing the halftone phase shift mask illustrated in FIG. 1;

FIG. 3 is a plan view showing a defect in the conventional halftone phase shift mask;

FIG. 4 is a perspective view illustrating an exemplary structure of a halftone phase shift mask according to the present invention;

FIG. 5 is a plan view of the halftone phase shift mask illustrated in FIG. 4; and

FIGS. 6A-6I are cross-sectional views illustrating steps of manufacturing the halftone phase shift mask illustrated in FIG. 4.

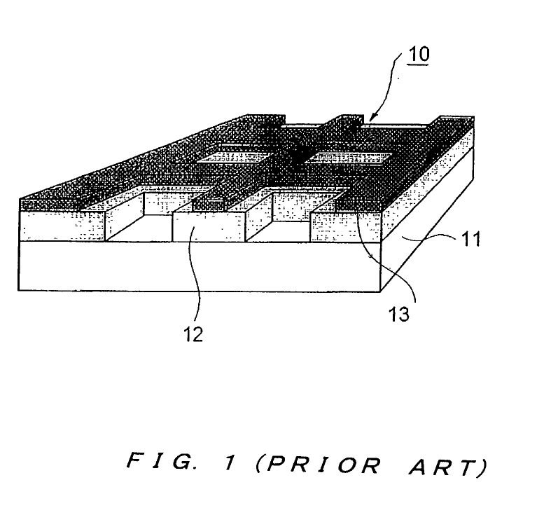

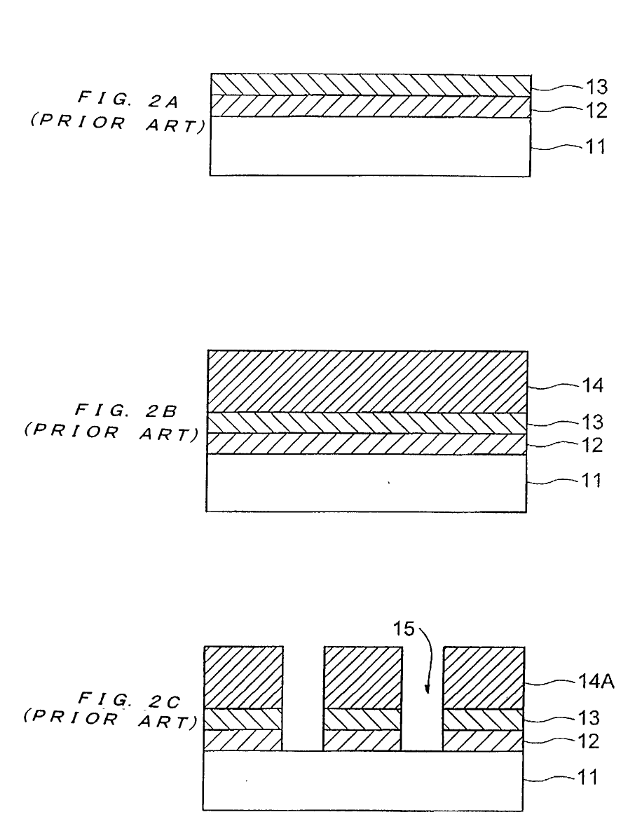

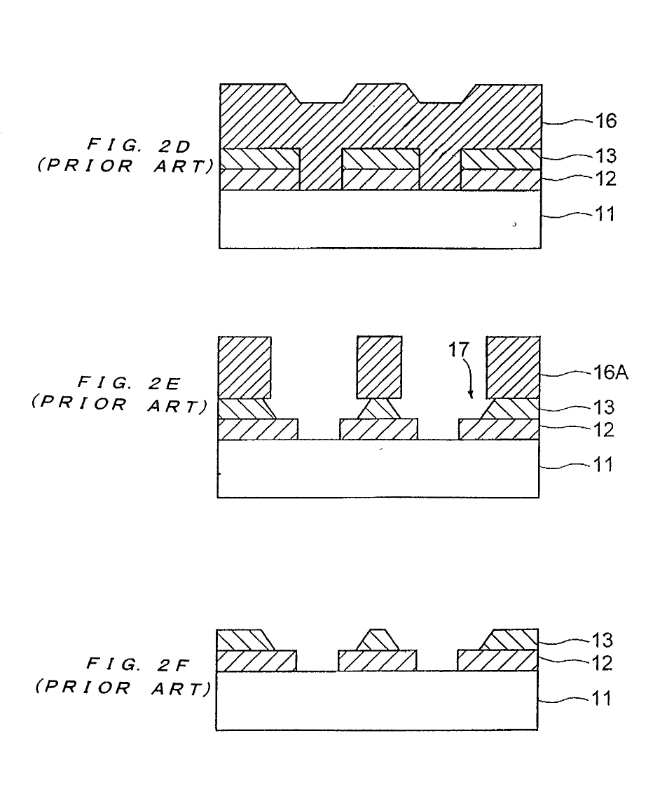

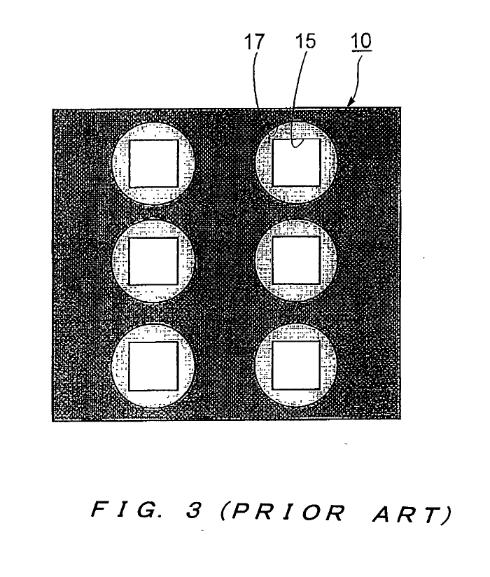

### DETAILED DESCRIPTION OF THE PREFERRED EMBODIMENT

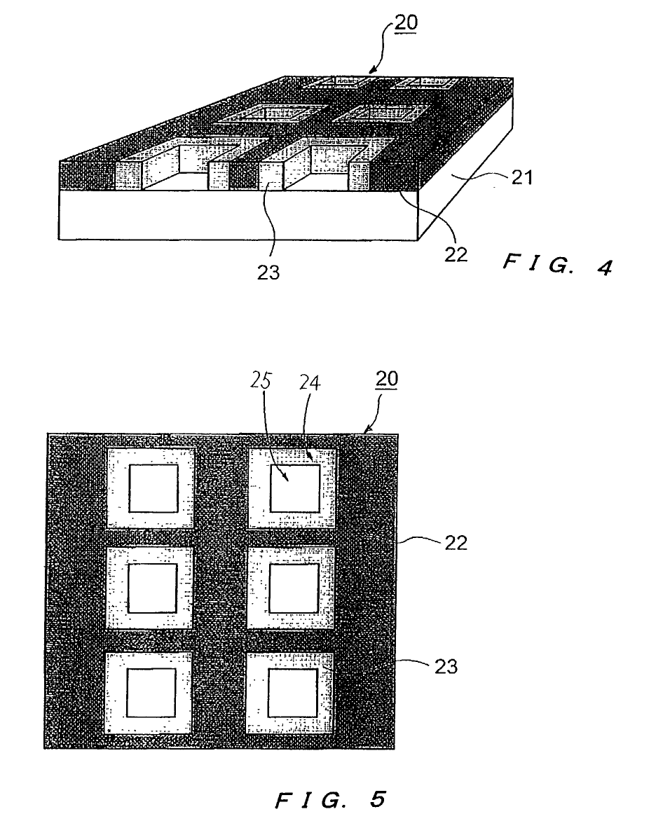

FIGS. 4 and 5 illustrate the structure of a halftone phase shift mask according to one embodiment of the present invention.

As illustrated in FIGS. 4 and 5, halftone phase shift mask 20 according to this embodiment comprises transparent substrate 21 made of glass; light shielding film 22 formed on transparent substrate 21, having first openings 24, and defining a light shielding region; and halftone film 23 formed within first openings 24 of light shielding film 22, defining translucent regions and functioning as a phase shift film. Halftone film 23 is formed with second openings 25 which define exposed regions.

Halftone film 23 and light shielding film 22 are respectively formed, for example, in a thickness of 140 nm. First openings 24 are each formed, for example, in a size of 4 μm×4 μm, and second openings 25 are each formed, for example, in a size of 1 μm×1 μm. Also, second openings 25 are formed such that their centers match those of first openings 24.

Halftone phase shift mask 20 according to this embodiment is used, for example, in a step of forming contact holes of 0.15 μm×0.15 μm by a KrF lithographic method with a reduction ratio set at ⅕. In this event, the dimension of a contact on a wafer corresponding to the reduction ratio is 0.2 μm with respect to the length of one side of second opening 25. However, smaller contact holes can be formed by adjusting the amount of exposure light.

According to the structure of halftone phase shift mask 20 in this embodiment, since halftone 23 is not laminated on light shielding film 22, a step of selectively removing light shielding film 22 is not required, as would be otherwise done in the prior art, and dry etching, which is anisotropic etching, can be used in the step of forming first openings 24. Since the dry etching can form openings at a high dimensional accuracy in an etching process using a resist as a mask, first openings 24 can be formed through light shielding film 22 at an improved dimensional accuracy. Similarly, since the dry etching can also be used in the step of forming second openings 25, second openings 25 can be formed through halftone film 23 likewise at an improved dimensional accuracy.

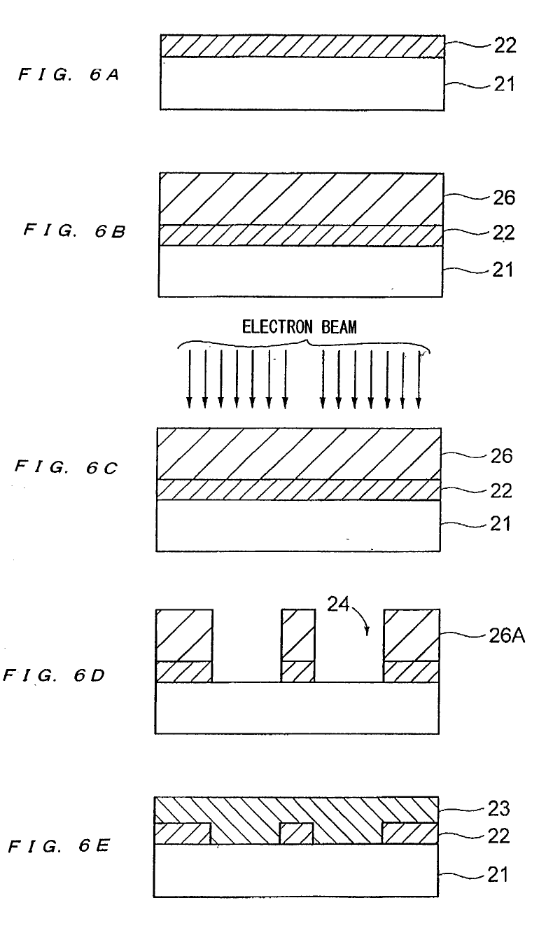

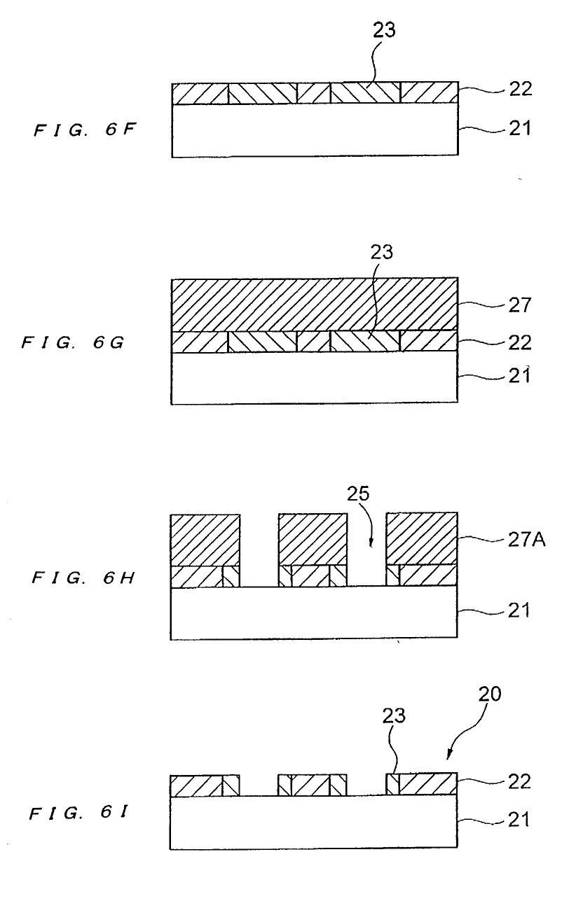

FIGS. 6A-6I illustrate steps of manufacturing the halftone phase shift mask according to this embodiment.

First, light shielding film 22 of 140 nm thick, for example, is deposited over the entire surface of transparent glass substrate 21 by a sputtering method (FIG. 6A). A Cr film, for example, may be used for light shielding film 22. Then, a resist is coated on light shielding film 22 using a known spin-coating method to form resist film 26 (FIG. 6B). Then, resist film 26 is patterned into a desired shape using a known electron beam (EB) drawing apparatus (FIG. 6C) to form resist pattern 26A.

Next, using resist pattern 26A as a mask, dry etching is performed with a chlorine gas to pattern light shielding film 22 to form first openings 24 through light shielding film 22 (FIG. 6D). Subsequently, halftone film 23 of sufficient thickness is deposited over the entire surface of light shielding film 22 including the insides of first openings 24 by a sputtering method (FIG. 6E). A chromium fluoride, for example, may be used for halftone film 23.

Then, halftone film 23 on light shielding film 22 is polished away by a CMP method using potassium hydroxide or ammonium hydroxide as a slurry (FIG. 6F). The CMP-based polishing is terminated at the time light shielding film 22 is exposed. In other words, light shielding film 22 is used as a stopper for the CMP-based polishing. Generally, while the CMP-based polishing experiences difficulties in accurately controlling the thickness, halftone film 23 can be accurately controlled in thickness by stopping the CMP-based polishing at the time it reaches the surface of light shielding film 22 which is accurately formed in a desired thickness by sputtering or the like in the foregoing manner, so that halftone film 23 can be accurately formed in a desired thickness.

Next, a resist is coated over the entire surface including light shielding film 22 and halftone film 23 by a spin-coating method to form resist film 27 (FIG. 6G).

Subsequently, resist film 27 is patterned using a known mask drawing apparatus to form resist pattern 27A which has openings smaller than first openings 24. Using this resist pattern 27A as a mask, halftone film 23 is patterned by dry etching with a chlorine gas to form second openings 25 through halftone film 23 (FIG. 6H).

Finally, resist pattern 27A is removed to complete halftone phase shift mask 20 according to this embodiment (FIG. 6I).

In the method of manufacturing the halftone phase shift mask according to this embodiment, dry etching is used for etching light shielding film 22 as well as halftone film 23. Since dry etching can accurately pattern the films along the shapes of openings formed through the resists, first openings 24 and second openings 25 can be formed at a high accuracy.

Also, since light shielding film 22 formed by a sputtering method is utilized as a stopper for the CMP-based polishing, halftone film 22 for use as a phase shift film can be accurately formed in a desired thickness. Further, as resist films 26, 27 have flat surfaces since they are deposited on flat underlying surfaces, resist patterns 26A, 27A provide an improved patterning accuracy.

Consequently, the halftone phase shift mask manufactured by the foregoing manufacturing method according to this embodiment has the ability to form openings in accurately controlled dimensions through either of the light shielding film and halftone phase shift film, so that the halftone phase shift mask can be used suitably in a minute patterning step particularly in a semiconductor integrated circuit device.

The material for resist films 26, 27 may be either of a positive type or a negative type resist.

While the foregoing description has been made in connection with a mask for use in the formation of contact holes in a semiconductor integrated circuit device, which is taken as an example of the halftone phase shift mask, the halftone phase shift mask of the present invention can be used in the formation of any minute pattern. In addition, the materials and dimensions illustrated in the foregoing embodiment can be conveniently selected depending on a particular pattern to be formed, and used exposure light.

Further, while the transparent substrate used in the foregoing embodiment is not particularly limited, a glass substrate is typically used. It should be noted that even if any film is formed on a transparent film, the substrate including the film formed thereon is referred to as a transparent substrate as long as the film is transparent. Also, though not particularly limited, the light shielding film may be suitably made of a Cr film. In addition, though not particularly limited, the halftone film may be suitably made, for example, of chromium oxide, chromium nitride, chromium oxynitride, chromium fluoride, molybdenum silicide, oxide of molybdenum silicide, SOG (Spin On Glass) glass, and the like.

While a preferred embodiment of the present invention has been described using specific terms, such description is for illustrative purposes only, and it is to be understood that changes and variations may be made without departing from the spirit or scope of the following claims.

What is claimed is:

1. A halftone phase shift mask comprising:
a transparent substrate;
a light shielding film formed on said transparent film for shielding exposure light, said light shielding film having a first opening; and
a halftone phase shift film formed in said first opening on said transparent substrate for shifting the phase of said exposure light, said halftone phase shift film having a second opening which defines an exposed region.

2. The halftone phase shift mask according to claim 1, wherein said light shielding film and said halftone phase shift mask have flat surfaces.

3. A method of manufacturing a halftone phase shift mask comprising:
a first step of forming a light shielding film on a transparent substrate for shielding exposed light;
a second step of forming a first opening through said light shielding film;
a third step of depositing a halftone phase shift film over the entire surface of said light shielding film including the inside of said first opening for shifting the phase of said exposure light;
a fourth step of polishing away said halftone phase shift film on said light shielding film while leaving said halftone phase shift film within said first opening; and
a fifth step of forming a second opening which defines an exposed region through said halftone phase shift film.

4. The method of manufacturing a halftone phase shift mask according to claim 3, wherein:
said fourth step includes stopping the polishing of said halftone phase shift film at a time the surface of said light shielding film is exposed.

5. The method of manufacturing a halftone phase shift mask according to claim 3, wherein:
said second step includes forming said first opening by dry etching, using a resist film including an opening patterned in a desired shape as a mask.

6. The method of manufacturing a halftone phase shift mask according to claim 3, wherein:
said fifth step includes forming said second opening by dry etching, using a resist film including an opening patterned in a desired shape as a mask.
